(19) United States
(12) Patent Application Publication
(10) Pub. No.: US 2008/0014751 A1
(43) Pub. Date: Jan. 17, 2008

(54) Method of manufacturing semiconductor device

(75) Inventors: Kozue Tanaka, Kawasaki (JP); Akira Kubo, Kawasaki (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, Kawasaki (JP)

(21) Appl. No.: 11/822,218

(22) Filed: Jul. 3, 2007

(30) Foreign Application Priority Data
Jul. 11, 2006 (JP) 2006-190196

(51) Int. Cl. H01L 21/302

(52) U.S. Cl. 438/693; 257/E21.002

(57) ABSTRACT

A method of manufacturing semiconductor device, providing the CMP method in a stable manner. A SiO₂ film 104 is formed on or above a silicon substrate 101, and the SiO₂ film 104 is processed by chemical mechanical polishing. The chemical mechanical polishing includes a first polishing process polishing the SiO₂ film 104 while supplying a first polishing agent containing abrasive grains, and an additive composed of a surfactant or a polymer salt; a second polishing process, following the first polishing process, dressing a polishing pad while polishing the film while supplying a liquid capable of dissolving the additive but contains no abrasive grains nor an additive composed of a surfactant or a polymer salt; and a third polishing process, following the second polishing process, further polishing the SiO₂ film 104 while supplying a second polishing agent which contains abrasive grains and an additive composed of a surfactant or a polymer salt, but without supplying the liquid.

This application is based on Japanese patent application No. 2006-190196 the content of which is incorporated hereinto by reference.

### BACKGROUND

1. Technical Field

The present invention relates to a method of manufacturing a semiconductor device, and in particular to a method of manufacturing a semiconductor device including a process of subjecting a film formed on or above a semiconductor substrate to chemical mechanical polishing.

2. Related Art

In accelerated trends in higher integration and dimensional shrinkage in semiconductor fabrication, chemical mechanical polishing (CMP) has been attracting public attention as a technique of planarization based on polishing.

For example, as for CMP technique for shallow trench isolation (STI) (also referred to as STICMP, hereinafter), technique of filling the STI groove with an insulating film to be used and a method of polishing the insulating film have been examined. Polishing agent used for STICMP generally contains an additive typically composed of a surfactant, in order to suppress excessive polishing during a CMP process (Japanese Laid-Open Patent Publication No. 2004-296600).

When using the polishing agent with the additive, progress of polishing is inhibited after the surface of the film was almost completely planarized. It has therefore been anticipated that polishing residue would occur, and the product (semiconductor chip) yield would degrade.

Known remedies for the polishing residue include those described in Japanese Laid-Open Patent Publication Nos. 2005-64450, 2005-340325, 2004-47676 and 2004-296591.

For example, Japanese Laid-Open Patent Publication No. 2005-64450 adopts a method of polishing under concomitant supply of polishing agent and pure water in the final stage of a polishing process. Polishing rate in this method reportedly increases, because the abrasive grains are supplied while reducing concentration of the additive which suppresses polishing.

Also other literatures propose methods of supplying, in the final stage of a polishing process, the polishing agent and water, and methods of polishing using water only (without using the polishing agent).

Although exemplary cases of STICMP have been explained, stable polishing process is generally required for the CMP process in any other step of the semiconductor device fabrication.

For example, Japanese Laid-Open Patent Publication No. 2003-31577 describes conditioning of a polishing pad, between a first stage and a second stage of CMP. The conditioning refers to a process of roughening the polishing pad using a diamond tool.

### SUMMARY

Although various techniques for the CMP process have been proposed as described in the above, the methods described in Japanese Laid-Open Patent Publication Nos. 2004-296600, 2005-64450, 2005-340325, 2004-47676 and 2004-296591 have sometimes failed in stable polishing due to gradual changes in concentration of the abrasive grains and the additive reside on the polishing pad during CMP process. Polishing using water only at the final stage has occasionally resulted in polishing residue.

Also in the method of the conditioning only of the polishing pad described in Japanese Laid-Open Patent Publication Nos. 2003-31577, there have some concern about the polishing residue because of the additive and the abrasive grains remaining on the surface of wafers.

According to the present invention, there is provided a method of manufacturing a semiconductor device which includes:

forming a film on or above a semiconductor substrate; and

subjecting the film to chemical mechanical polishing,

wherein the chemical mechanical polishing further includes:

a first polishing process polishing the film while supplying a first polishing agent which contains abrasive grains, and an additive composed of a surfactant or a polymer salt;

a second polishing process, following the first polishing process, dressing a polishing pad while polishing the film with supplying a liquid capable of dissolving the additive but contains no abrasive grains nor an additive composed of a surfactant or a polymer salt; and

a third polishing process, further polishing the film while supplying a second polishing agent which contains abrasive grains and an additive composed of a surfactant or a polymer salt, but without supplying the liquid.

As described above in the “Related Art”, the conventional methods for the case where a polishing agent containing an additive composed of a surfactant or a polymer salt, and abrasive grains was used, have suffered from that the polishing of the film was suppressed after the surface of the film was planarized, and thereby the polishing residue occurred.

This is supposedly because the additive adheres to the surface of the film, although causes still remain not fully clarified.

Therefore in the present invention, in the process of chemical mechanical polishing of the film, the second polishing process is provided after the first polishing process and prior to the third polishing process. In the second polishing process, the polishing pad is dressed while polishing the film with supplying a liquid capable of dissolving the additive but contains no abrasive grains nor an additive composed of a surfactant or a polymer salt.

In this configuration, the additive remaining in the vicinity of the surfaces of the polishing pad and the semiconductor substrate after the first polishing process can be dissolved into the liquid in the second polishing process, and is washed off. Therefore, the additive remaining in the vicinity of the surfaces of the polishing pad and the semiconductor substrate can thoroughly be removed in the second polishing process. Alternatively, the abrasive grains remaining in the vicinity of the polishing pad and the semiconductor substrate may be washed off and removed, when the polishing pad is dressed while supplying the liquid and polishing the film.

As has been described in the above, the surfaces of the polishing pad and the semiconductor substrates are refreshed in the second polishing process in the present invention, polishing of the semiconductor substrate in the succeeding third polishing process can proceed in a stable manner. The polishing residue which could occur after the third polishing process can now be suppressed, even when both polishing agents used in the first and the third polishing processes contain the abrasive grains and the additive.

In the present invention, the first polishing agent used in the first polishing process and the second polishing agent used in the third polishing process may be the same, or different from each other. For the case where the second polishing process is not provided, use of the same first and second polishing agents has sometimes inhibited the polishing as described above in the Related Art. In contrast, the present invention adopts the second polishing process in which the surfaces of the semiconductor substrate and the polishing pad are refreshed, so that the film can thoroughly be polished in the third polishing process, even when the same first and second polishing agents are used.

Japanese Laid-Open Patent Publication No. 2005-64450 mentioned above in the Related Art describes that the additive is removed by water jet, between the main polishing under supply of the polishing agent and the final stage of the polishing under supply of the polishing agent and pure water. In this case, the process of the final stage of the polishing has sometimes resulted in variation in concentration of the polishing agent over the polishing pad, because the polishing agent and water have separately been supplied. The polishing has not, therefore, been proceeded in a stable manner as described above.

In contrast in the present invention, the polishing can stably be proceeded without causing in-plane variation in the concentration of the polishing agent over the polishing pad, because the polishing in the third polishing process is proceeded while supplying the second polishing agent but without supplying the liquid.

In the present invention, the second polishing agent supplied in the third polishing process may contain any component of the liquid supplied in the second polishing process.

As has been described in the above, the present invention can polish the film by CMP in a stable manner and can suppress the polishing residue.

### BRIEF DESCRIPTION OF THE DRAWINGS

The above and other objects, advantages and features of the present invention will be more apparent from the following description of certain preferred embodiments taken in conjunction with the accompanying drawings, in which:

FIGS. 1 to 3 are sectional views showing process steps of manufacturing the semiconductor device shown in FIG. 4;

FIG. 4 is a sectional view showing a configuration of a semiconductor device in one embodiment;

FIGS. 5 to 7 are sectional views showing process steps of manufacturing the semiconductor device shown in FIG. 8;

FIG. 8 is a sectional view showing a configuration of a semiconductor device in another embodiment;

FIG. 9 is a flow chart showing procedures of polishing in the embodiments;

FIG. 10 is a drawing showing a condition of a wafer surface in an example; and

FIG. 11 is a drawing showing a condition of a wafer surface in a comparative example.

### DETAILED DESCRIPTION

The invention will be now described herein with reference to an illustrative embodiment. Those skilled in the art will recognize that many alternative embodiments can be accomplished using the teachings of the present invention and that the invention is not limited to the embodiment illustrated for explanatory purposes.

Embodiments of the present invention will be explained below referring to the attached drawings. It is to be noted that any common constituents will be added with the same reference numerals, so as to occasionally avoid repetitive explanation.

### First Embodiment

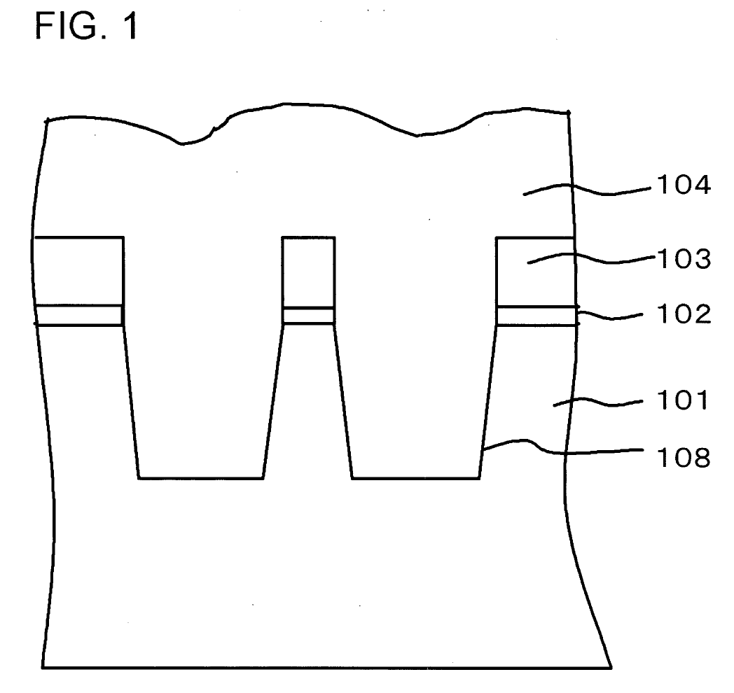

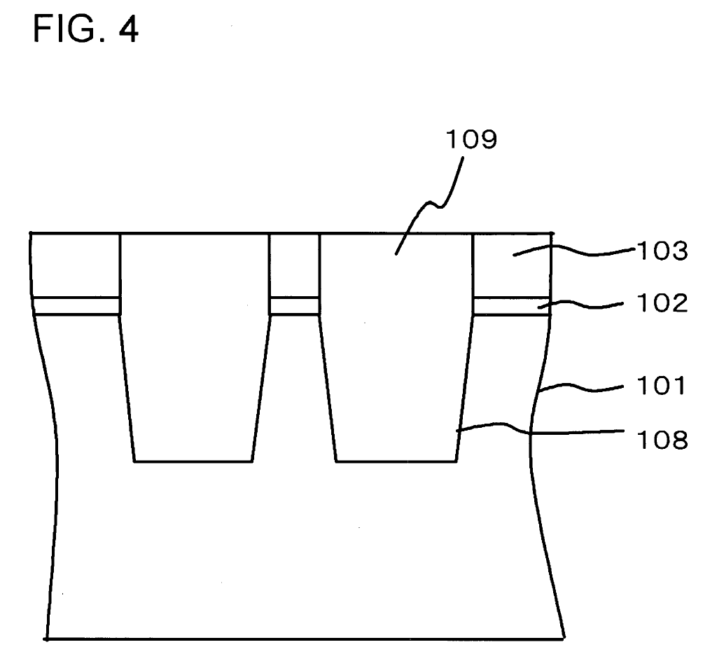

FIGS. 1 to 3 are sectional views showing process steps of manufacturing the semiconductor device shown in FIG. 4. FIG. 4 is a sectional view showing a configuration of a semiconductor device in this embodiment.

In the semiconductor device shown in FIG. 4, a SiO₂ film 102 and a SiN film 103 are stacked in this order on the device-forming surface of a silicon substrate 101. Trench-like concave portions 108 are provided in predetermined regions, so as to range in depth from the SiN film 103 to the silicon substrate 101. Element isolation regions 109 based on STI are configured by a SiO₂ film filled in the concave portions 108.

A method of manufacturing the semiconductor device shown in FIG. 4 will be explained in the next.

The method of manufacturing includes a process step of forming a film (a SiO₂ film 104) on or over the silicon substrate 101.

This embodiment and the other embodiment described later will explain exemplary cases where the film to be polished is an insulating film (first insulating film).

The method of manufacturing according to this embodiment further includes the process steps of;

forming, prior to the process of forming the SiO₂ film 104, a second insulating film (the SiN film 103) in contact with the upper portion of the silicon substrate 101; and

selectively removing, following the process of forming the SiN film 103, and prior to the process of forming the SiO₂ film 104, predetermined portions of the SiN film 103 and silicon substrate 101, to thereby form the concave portions 108 ranging in depth from the SiN film 103 to the inner portion of the silicon substrate 101.

More specifically, first as shown in FIG. 1, the SiO₂ film 102 and the SiN film 103 are sequentially formed on the silicon substrate 101. The silicon substrate 101 is typically a silicon wafer. The SiO₂ film 102 is typically a thermal oxide film. Next, with the aid of photolithographic technique and dry etching technique, predetermined portions of the SiN film 103, the SiO₂ film 102 and the silicon substrate 101 are selectively removed, to thereby form the trenches (concave portions 108). Next, on the concave portions 108 and the SiN film 103, the SiO₂ film 104 is formed so as to fill the concave portions 108. The SiO₂ film 104 is typically an HDP (high-density plasma) film or a SACVD (sub-atmospheric chemical vapor deposition) film. This configuration is successful in further improving filling performance of the film into the concave portions 108. The thickness of the SiO₂ film 104 is typically adjusted to 600 nm or around.

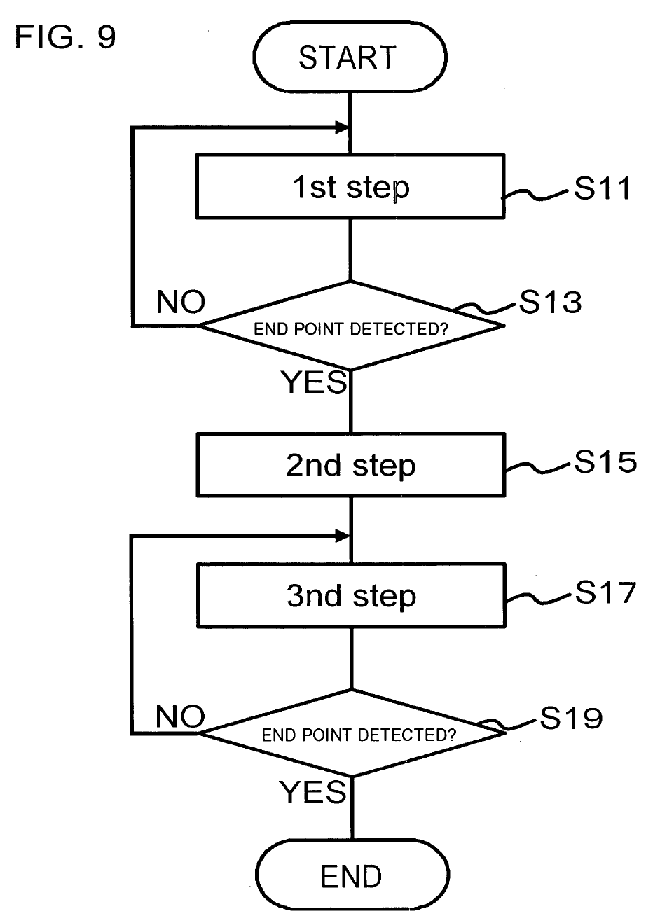

The SiO₂ film 104 is then polished by CMP until the surface of the SiN film 103 exposes. The FIG. 9 is a flow chart showing procedures of CMP in the method of manufacturing a semiconductor device according to this embodiment. In this embodiment, and in the other embodiment described later, the CMP process is carried out according to the procedures as follows.

As shown in FIG. 9, in the CMP process, step 11 (S11): first polishing process (1st step); step 15 (S15): second polishing process (2nd step); and step 17 (S17): third polishing process (3rd step) are carried out in this order. In this embodiment, step 11 is a process of planarizing the SiO₂ film 104, and step 17 is a process of further polishing thus-planarized SiO₂ film 104.

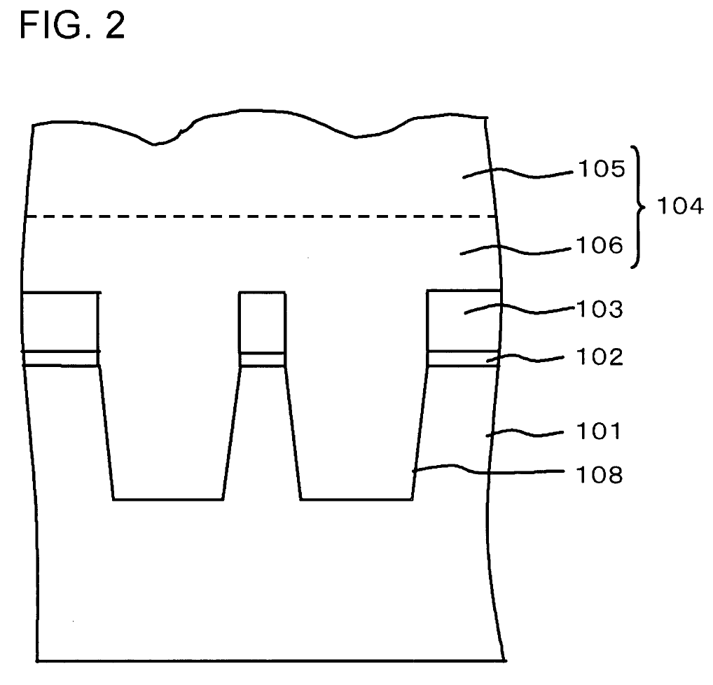

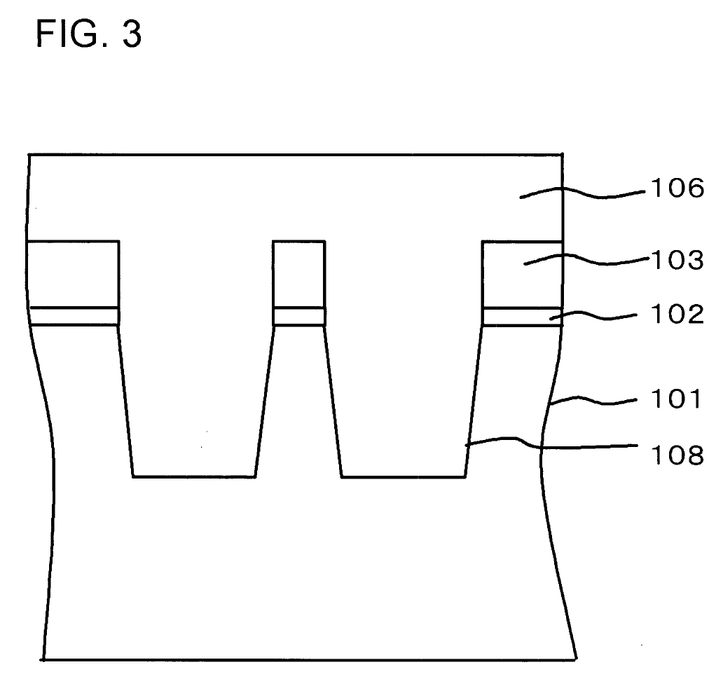

The first polishing process in step 11 is a process of polishing the SiO₂ film 104, while supplying the first polishing agent which contains abrasive grains and the additive composed of a surfactant or a polymer salt. In step 11, the upper portion 105, shown in FIG. 2, of the SiO₂ film 104 is removed by polishing, and thereby the polished surface is planarized (FIG. 3).

The abrasive grains contained in the first polishing agent are typically those of ceria or silica. The description below will be made on the case where the abrasive grains are composed of ceria. The additive has a function of preventing the polishing from excessively proceeding, and is typically composed of a surfactant such as polycarboxylic acid polymer, or a polymer salt.

Upon detection of the end point of the first polishing process (YES in S13), supply of the first polishing agent is stopped. The end point is detectable in a form of electric signal such as current, which indicates change in motor torque as the upper portion 105 of the film is planarized. Upon completion of the first polishing process, thickness of the lower portion 106 of the film remaining on the SiN film 103 is adjusted typically to 50 nm or more. According to this configuration, the end point of the third polishing process, described later, can be detected in a further stable manner (S19). Thickness of the lower portion 106 of the film to be remained on the SiN film 103 is adjusted to 200 nm or below, for example. According to this adjustment, the lower portion 106 of the film can thoroughly be polished in the third polishing process, even when ceria is used as the abrasive grains, and thereby the top surface of the SiN film 103 can be exposed. Thickness of the SiO₂ film 104 to be remained on the SiN film 103 is more specifically adjusted to 100 nm or around.

Next, the second polishing process of step 15 is carried out over a predetermined duration of time. This process is aimed at dissolving the additive, and dressing the polishing pad while polishing the SiO2 film 104 and supplying a liquid which contains no abrasive grains nor an additive composed of a surfactant or a polymer salt. In order to remove, by dressing, polishing debris or the polishing agent remained on the surface of the polishing pad, and to set (roughen) the surface of the pad for the next polishing, the surface of the pad is dressed under a predetermined pressure and rotation speed, using a plate having a plurality of diamond abrasive grains immobilized thereon, while supplying a fluid (liquid) onto the surface of the pad.

Water can be exemplified as the liquid capable of dissolving the additive contained in the first polishing agent, but containing no abrasive grains nor an additive composed of a surfactant or a polymer salt, wherein pure water is adoptable in a particularly preferable manner.

In step 15, the pure water is supplied through a nozzle of a polishing machine. The pure water is supplied typically to the portion at around the center of the polishing pad. The pure water may be supplied also in a curtain-like manner in the radial direction of the polishing pad. According to this configuration, the pure water can be supplied over the entire surface of the polishing pad, so that the additive used in step 11 can further thoroughly be washed off and removed from the entire surfaces of the polishing pad and the silicon substrate 101.

Step 15 is carried out at lower pressures than in the first and third polishing processes. According to this configuration, the additive and the abrasive grains contained in the first polishing agent used in the first polishing process can thoroughly be removed, and the surfaces of the polishing pad and the silicon substrate 101 can be refreshed. Pressure of polishing in the second polishing process is adjusted, for example, to 1 psi or below. By this adjustment, the additive and the abrasive grains contained in the first polishing agent can further thoroughly be removed, and the scratching on the surface of the silicon substrate 101 can more surely be suppressed. The lower limit of the pressure of polishing in the second polishing process is typically adjusted to 0.01 psi or above, although being not specifically limited.

Polishing time in the second polishing process is good enough if the additive contained in the first polishing agent can be removed, and is typically adjusted to 10 seconds or longer. The polishing time in the second polishing process is also adjusted to 30 seconds or shorter, for example. Excessively long polishing time may result in degradation in the throughput and shortening of the service life of the polishing pad. By limiting the polishing time to 30 seconds or shorter, the surface of the silicon substrate 101 is more successfully prevented from being scratched, even when the polishing is carried out while supplying the liquid which contains no abrasive grains nor an additive.

Thereafter, the third polishing process of step 17 is carried out. This process, following step 15, is aimed at further polishing the SiO₂ film 104, while supplying the second polishing agent which contains the abrasive grains and an additive composed of a surfactant or a polymer salt, but without supplying the liquid used in step 15. In this embodiment, step 17 can be understood as an over-polishing process of the SiO₂ film 104. As shown in FIGS. 3 and 4, the portion of the SiO₂ film 104 formed on the SiN film 103 is removed in this process, and thereby the surface of the SiN film 103 is exposed in the region other than the region having the concave portions 108 formed therein.

The second polishing agent used in the step 17 may be same as, or different from the first polishing agent, so far as it contains the abrasive grains and the additive.

The end point of step 17 is determined typically by detecting an electric signal such as current, which indicates change in motor torque as the top surface of the SiN film 103 exposes. Upon detection of the end point (YES in S19), supply of the second polishing agent is stopped. Pure water is then supplied onto the polishing pad, to thereby clean the surfaces of the polishing pad and the silicon substrate 101.

After completion of these processes, the semiconductor device shown in FIG. 4 is obtained. It is also allowable thereafter to form predetermined elements such as transistors, or a multi-layered interconnect structure on the silicon substrate 101.

In this embodiment, there is provided, between step 11 and step 17, a low-pressure water polishing and dressing process of step 15, which is a process of allowing polishing and dressing to simultaneously proceed using water under low polishing pressure. According to this configuration, the abrasive grains and the additive remaining on the polished surface of the silicon substrate 101 and on the polishing pad can thoroughly be removed, and the surface of the polishing pad is refreshed. For this reason, polishing of the lower portion 106 of the film can now be proceeded in a more exact manner in step 17, as compared with the case having no step 15 provided thereto. In this embodiment, provision of step 15 makes it possible to thoroughly polish the lower portion 106 of the film in step 17, even when the same first and second polishing agents are used, wherein the second polishing agent may be different from the first polishing agent, depending on purposes of the polishing.

Unlike the method of Japanese Laid-Open Patent Publication No. 2005-64450 described in the above, this embodiment supplies only the polishing agent in step 17, rather than separately supplying pure water and polishing agent, so that both of the abrasive grains and the additive can be used under stable concentration over the duration of time from the start to the end of the polishing. It is therefore made possible to suppress in-plane variation in proceeding of the polishing on the wafer used as the silicon substrate 101, and to carry out the polishing in a stable manner. It is to be noted that the liquid used in step 15, more specifically water, may be contained in the second polishing agent.

As has been described in the above, this embodiment can suppress the polishing residue ascribable to inhibition of polishing in the so-called, over-polishing region after the end point detection (YES in S13). It is therefore made possible to suppress residue of the SiN film 103 under the SiO₂ film 104 in the succeeding diffusion process, and to improve the yield of the products.

The embodiment hereinafter will be explained placing an emphasis on the points differing from those in the first embodiment.

### Second Embodiment

In this embodiment, the method of polishing described above in the first embodiment will be used for planarization of an interlayer insulating film.

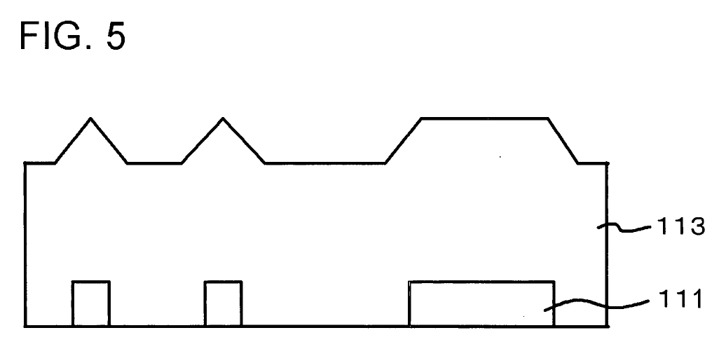

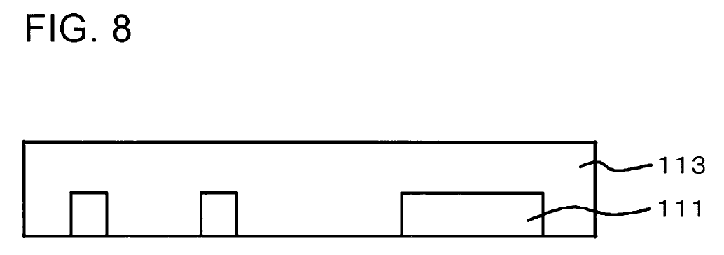

FIGS. 5 to 7 are sectional views showing the process steps of manufacturing the semiconductor device shown in FIG. 8. FIG. 8 is a sectional view showing a configuration of the semiconductor device of this embodiment.

The semiconductor device shown in FIG. 8 has a SiO₂ film 113 over a silicon substrate (not shown). The SiO₂ film 113 is an interlayer insulating film, and has interconnects 111 buried therein. The lower surfaces of the interconnects 111 is aligned at the same level with the lower surface of the SiO₂ film 113. A material composing the interconnects 111 is typically a copper-containing metal. It is also allowable to provide a predetermined number of interlayer insulating films between the silicon substrate (not shown) and the SiO₂ film 113, and conductive components such as interconnects and connection plugs may be buried in the interlayer insulating films.

Next, a method of manufacturing a semiconductor device shown in FIG. 8 will be explained. Basic procedures for the method of manufacturing are those used for the method described in the first embodiment.

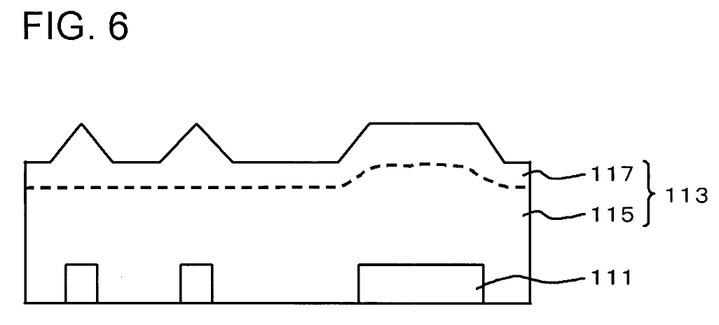

First, as shown in FIG. 6, the interconnects 111 are formed on a predetermined film (not shown) on or above the silicon substrate (not shown). The SiO₂ film 113 is then formed on the interconnects 111 so as to cover the interconnects 111.

Next, the SiO₂ film 113 is planarized by the procedures described in the above referring to FIG. 9.

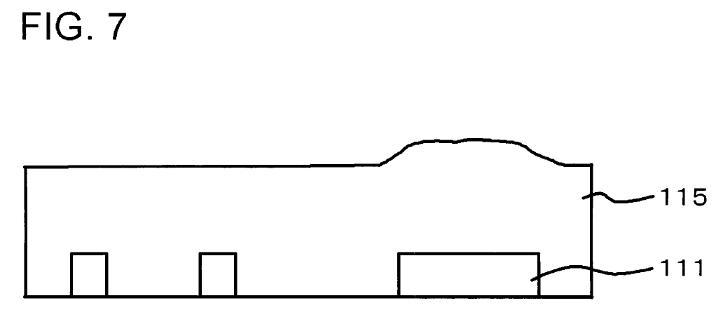

First, the upper portion 117 of the film is removed by polishing in the first polishing process of step 11 (FIG. 7). In step 13, the end point is set as being detected, for example, when the upper portion 117 of the film is polished, and thereby the surface of the SiO₂ film 113 is planarized to a certain extent.

Upon detection of the end point (YES in S13), supply of the first polishing agent is stopped, and simultaneous polishing and dressing using water is carried out as the second polishing process of step 15.

The residual lower portion 115 of the film is further polished in the third polishing process of step 17, to thereby planarize the surface, and to thin the film to a predetermined thickness. In step 19, the end point is set as being detected, for example, when the lower portion 115 of the film is thinned to a predetermined thickness. Upon detection of the end point (YES in S19), supply of the second polishing agent is stopped.

According to these procedures, the semiconductor device shown in FIG. 8 is obtained.

Also in this embodiment, the process of polishing the SiO₂ film 113 has step 15 provided between step 11 and step 17, and thereby the effects same as those in the first embodiment can be obtained. If the above-described procedures are applied to the process of polishing the SiO₂ film 113 as an interlayer insulating film, in-plane uniformity of the SiO₂ film 113 can further be improved, and thereby the flatness can be improved.

The paragraphs in the above have explained embodiments of the present invention referring to the attached drawings, wherein these embodiments are mere examples of the present invention, allowing adoption of various configurations other than those described in the above.

For example, the embodiments in the above have explained the exemplary cases of the CMP process for the insulating film formed over the silicon substrate 101, wherein the method of manufacturing of the present invention is applicable not only to the CMP process for the insulating film, but also to the CMP process for conductive films.

### EXAMPLES

### Example

On a Si wafer having formed thereon, in a plan view, a plurality of 800 μm×800 μm square blocks, each block having small square trenches arranged in 10 lines and 10 rows (100 in total), a SiN film and a SiO₂ film (600 nm thick) were sequentially formed, and the SiO₂ film was removed by CMP. The procedures of polishing were same as those described previously referring to FIG. 9, wherein specific conditions adopted herein were as follows;
first polishing process (S11): ceria slurry, 6 psi, 35 seconds;
second polishing process (S15): pure water, 1 psi, 15 seconds; and
third polishing process (S17): ceria slurry, 3 psi, 75 seconds.

The same ceria slurry was used in the first and third polishing processes.

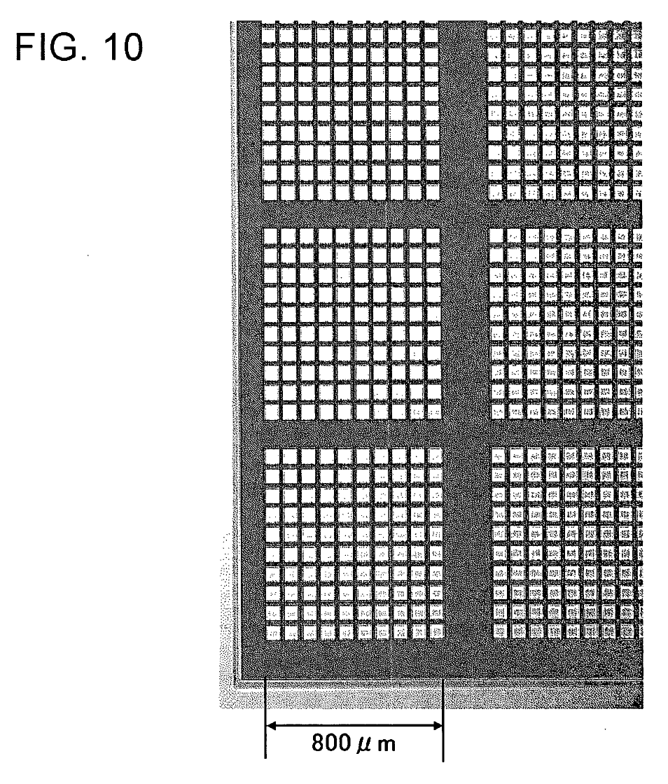

FIG. 10 is a drawing showing a condition of the surface of the wafer after the polishing. In this embodiment, the SiO₂ film could be polished in a stable manner over the entire surface of the wafer. As shown in FIG. 10, there was no polishing residue found on the surface of the wafer.

### Comparative Example

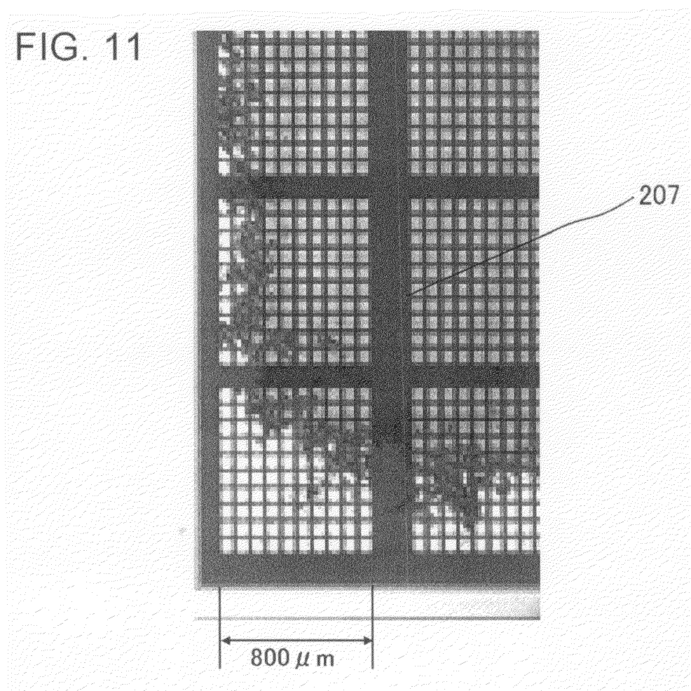

The first and third polishing processes were carried out in succession, without providing the second polishing process in between, unlike the example. FIG. 11 is a drawing showing a condition of the wafer after the polishing. As shown in FIG. 11, polishing residue 207 of the SiO₂ film was found on the surface of the wafer according to the method of Comparative Example.

It is apparent that the present invention is not limited to the above embodiment, that may be modified and changed without departing from the scope and spirit of the invention.

What is claimed is:

1. A method of manufacturing a semiconductor device comprising:
forming a film on or above a semiconductor substrate; and
subjecting said film to chemical mechanical polishing, wherein said chemical mechanical polishing further comprises:
a first polishing process polishing said film while supplying a first polishing agent which contains abrasive grains, and an additive composed of a surfactant or a polymer salt;
a second polishing process, following said first polishing process, dressing a polishing pad while polishing said film with supplying a liquid capable of dissolving said additive but contains no abrasive grains nor an additive composed of a surfactant or a polymer salt; and
a third polishing process, following said second polishing process, further polishing said film while supplying a second polishing agent which contains abrasive grains and an additive composed of a surfactant or a polymer salt, but without supplying said liquid.

2. The method of manufacturing a semiconductor device as claimed in claim 1,
wherein said liquid is water.

3. The method of manufacturing a semiconductor device as claimed in claim 1,
wherein said abrasive grains are those of ceria or silica.

4. The method of manufacturing a semiconductor device as claimed in claim 1,
wherein said second polishing agent is same as said first polishing agent.

5. The method of manufacturing a semiconductor device as claimed in claim 1,
wherein polishing pressure in said second polishing process is adjusted to 1 psi or below.

6. The method of manufacturing a semiconductor device as claimed in claim 1,
wherein said film is a first insulating film.

7. The method of manufacturing a semiconductor device as claimed in claim 6,
wherein said first insulating film is a SiO₂ film.

8. The method of manufacturing a semiconductor device as claimed in claim 6, further comprising:
forming, prior to said process of forming the film, a second insulating film in contact with the upper portion of said semiconductor substrate; and
selectively removing, following said process of forming the second insulating film, and prior to said process of forming the film, predetermined portions of said second insulating film and said semiconductor substrate, to thereby form a concave portion ranging in depth from said second insulating film to the inner portion of said semiconductor substrate,
wherein said process of forming said film is a process of forming said first insulating film so as to fill said concave portion, and
in said third polishing process, said first insulating film formed on said second insulating film in a region outside said concave portion is removed, to thereby expose the surface of said second insulating film.

9. The method of manufacturing a semiconductor device as claimed in claim 8,
wherein said first insulating film is a SiO₂ film, and said second insulating film is a SiN film.

10. The method of manufacturing a semiconductor device as claimed in claim 8,
wherein said first polishing process is a process of planarizing said first insulating film; and
said third polishing process is a process of further polishing said planarized first insulating film.

11. The method of manufacturing a semiconductor device as claimed in claim 6,
further comprising, prior to said process of forming the film, forming an interconnect on or above said semiconductor substrate, and
forming, in said process of forming the film, said first insulating film so as to cover said interconnect.
